(19) United States
(12) Patent Application Publication
(10) Pub. No.: US 2012/0223370 A1
(43) Pub. Date: Sep. 6, 2012

(54) BIOCHEMICAL SENSOR AND METHOD OF MANUFACTURING THE SAME

(76) Inventors: Hsiao-Wen ZAN, Hsinchu County (TW); Chuang-Chuang Tsai, Taipei City (TW); Hsin-Fei Meng, Hsinchu City (TW); Chun-Cheng Yeh, Taipei City (TW); Ming-Zhi Dai, Chiayi County (TW); Chang-Hung Li, New Taipei City (TW)

(21) Appl. No.: 13/114,728

(22) Filed: May 24, 2011

(30) Foreign Application Priority Data
Mar. 4, 2011 (TW) 100107303

(51) Int. Cl. H01L 29/66; H01L 21/02

(52) U.S. Cl. 257/253; 438/49; 257/E29.166; 257/E21.002

(57) ABSTRACT

A biochemical sensor and a method of manufacturing the same are disclosed. The biochemical sensor includes a substrate, a gate arranged on one side of the substrate, a gate insulating layer arranged on one side of the gate opposite to the substrate, an active layer arranged on one side of the gate insulating layer opposite to the gate, a source and a drain arranged on one side of the active layer opposite to the gate insulating layer, and a biochemical sensing layer arranged on one side of the active layer opposite to the gate insulating layer and between the source and the drain.

### FIELD OF THE INVENTION

The present invention relates to a biochemical sensor and structure thereof, and more particularly to a biochemical sensor having a biochemical sensing layer provided on back channel of a metal-oxide-semiconductor (MOS) transistor.

### BACKGROUND OF THE INVENTION

The prior art biochemical sensor uses a monomolecular organic thin film transistor as a component thereof. However, such biochemical sensor could not be mass-produced because the monomolecular film could not be easily stably formed. In addition, such biochemical sensor can only be applied to detection in a gaseous environment because it is usually difficult for the organic thin film transistor to operate in a liquid environment.

Among others, a metal-oxide-semiconductor (MOS) transistor has excellent current driving capacity, is producible at low temperature with relatively simple and matured process, and can be stored in air over long period of time without adversely affecting its operating characteristics. With these advantages, the MOS transistor has become the new generation of high potential component for manufacturing a biochemical sensor. However, the MOS transistor is completely formed of inorganic materials and therefore shows relatively poor response in sensing or detecting most part of chemicals. Thus, the biochemical sensor using MOS transistor as the component thereof still requires improvement.

It is therefore tried by the inventor to develop an improved biochemical sensor and a method of manufacturing the same, so as to overcome the drawbacks in the prior art biochemical sensors and provide the metal-oxide-semiconductor (MOS) transistor with effectively increased sensitivity and selectivity in detecting biochemical substances.

### SUMMARY OF THE INVENTION

A primary object of the present invention is to provide a biochemical sensor and method of manufacturing the same, so as to enable mass-production of biochemical sensors and to provide the MOS transistor with increased sensitivity and selectivity in sensing biochemical substances.

To achieve the above and other objects, the biochemical sensor according to the present invention includes a substrate, a gate arranged on one side of the substrate, a gate insulating layer arranged on one side of the gate opposite to the substrate, an active layer arranged on one side of the gate insulating layer opposite to the gate, a source and a drain arranged on one side of the active layer opposite to the gate insulating layer, and a biochemical sensing layer arranged on one side of the active layer opposite to the gate insulating layer and located between the source and the drain.

In an embodiment of the present invention, the biochemical sensing layer further includes a first biochemical sensing sublayer arranged on one side of the active layer opposite to the gate insulating layer, and a second biochemical sensing sublayer arranged on one side of the first biochemical sensing sublayer opposite to the active layer.

In another embodiment, the biochemical sensing layer is surface functionalized to thereby have biochemical selectivity.

In a further embodiment, the biochemical sensing layer is provided on a top surface with at least a first hole structure to enable increased contact area on the biochemical sensing layer.

In a still further embodiment, the active layer is provided on a top surface with at least a second hole structure to enable increased contact area on the active layer.

According to the present invention, the biochemical sensing layer is selected from the group consisting of 3-Hexylthiophene (P3HT), lead phthalocyanine (PbPC), and copper phthalocyanine (CuPC).

To achieve the above and other objects, the method of manufacturing biochemical sensor according to the present invention includes the steps of providing a substrate; arranging a gate on one side of the substrate; arranging a gate insulating layer on one side of the gate opposite to the substrate; arranging an active layer on one side of the gate insulating layer opposite to the gate; arranging a source and a drain on one side of the active layer opposite to the gate insulating layer; and arranging a biochemical sensing layer on one side of the active layer opposite to the gate insulating layer and between the source and the drain.

In an embodiment of the present invention, the biochemical sensing layer further includes a first and a second biochemical sensing sublayer, and the biochemical sensor manufacturing method further includes the steps of arranging the first biochemical sensing sublayer on one side of the active layer opposite to the gate insulating layer and between the source and the drain; and arranging the second biochemical sensing sublayer on one side of the first biochemical sensing sublayer opposite to the active layer.

In another embodiment, a method of manufacturing the biochemical sensor further includes the step of functionalizing a top surface of the biochemical sensing layer, so that the biochemical sensing layer has biochemical selectivity.

In a further embodiment, a method of manufacturing the biochemical sensor further includes the step of forming a first hole structure on a top surface of the biochemical sensing layer; wherein the first hole structure enables increased contact area on the biochemical sensing layer.

In a still further embodiment, a method of manufacturing the biochemical sensor further includes the step of forming a second hole structure on a top surface of the active layer; wherein the second hole structure enables increased contact area on the active layer.

Wherein, the biochemical sensing layer is selected from the group consisting of 3-Hexylthiophene (P3HT), lead phthalocyanine (PbPC), and copper phthalocyanine (CuPC).

According to the above-description, the biochemical sensor and the method of manufacturing the same according to the present invention provide one or more of the following advantages:

(1) The biochemical sensing layer is arranged on the active layer of the biochemical sensor to enable convenient use of the biochemical sensor to detect various types of biochemical substances, such as ammonia, nitrogen oxide, acetone, DNA molecules, protein and the like.

(2) The biochemical sensing layer can be surface functionalized to provide the biochemical sensor with increased detection sensitivity and biochemical selectivity.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1A is a schematic view of a biochemical sensor according to a first embodiment of the present invention;

FIG. 1B illustrates the use of the biochemical sensor according to the first embodiment of the present invention to sense gas;

FIG. 1C also illustrates the use of the biochemical sensor according to the first embodiment of the present invention to sense gas;

FIG. 1D illustrates the use of the biochemical sensor according to the first embodiment of the present invention to sense liquid;

FIG. 2 is a schematic view of a biochemical sensor according to a second embodiment of the present invention;

FIG. 3 is a schematic view of a biochemical sensor according to a third embodiment of the present invention;

FIG. 4 is a schematic view of a biochemical sensor according to a fourth embodiment of the present invention;

FIG. 5 is a schematic view of a biochemical sensor according to a fifth embodiment of the present invention;

FIG. 6A is a schematic view of a biochemical sensor according to a sixth embodiment of the present invention;

FIG. 6B illustrates the use of the biochemical sensor according to the sixth embodiment of the present invention to sense gas;

FIG. 7 is a schematic view of a biochemical sensor array according to the present invention; and

FIG. 8 is a flowchart showing the steps included in a method of manufacturing biochemical sensor according to the present invention.

### DETAILED DESCRIPTION OF THE PREFERRED EMBODIMENTS

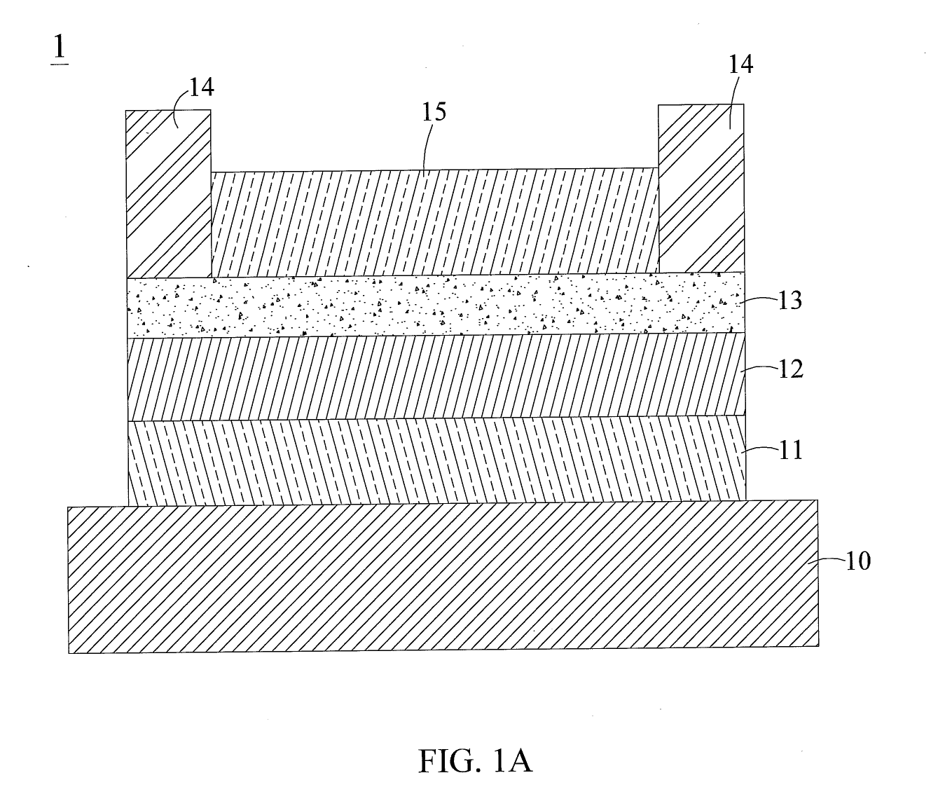

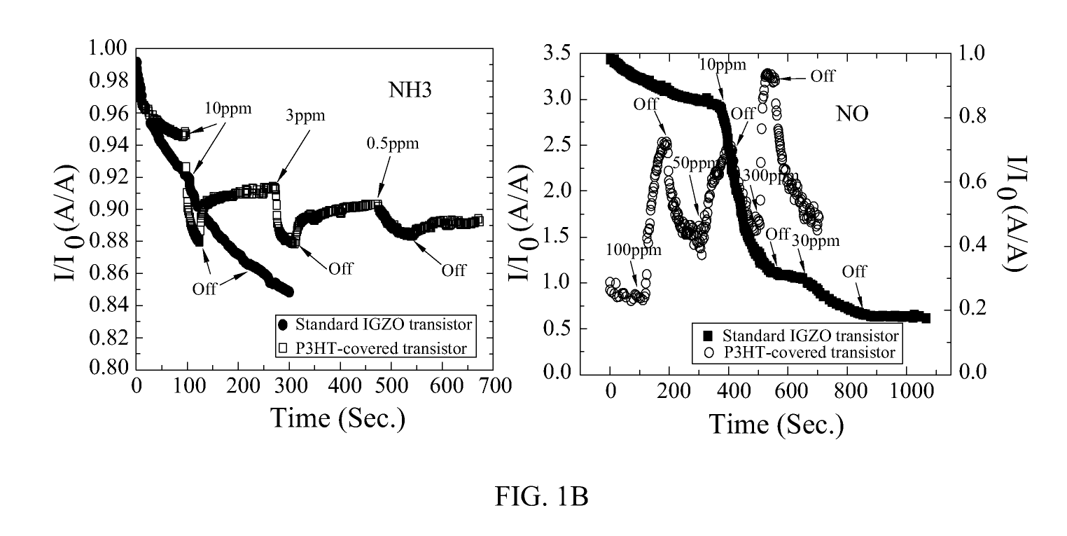

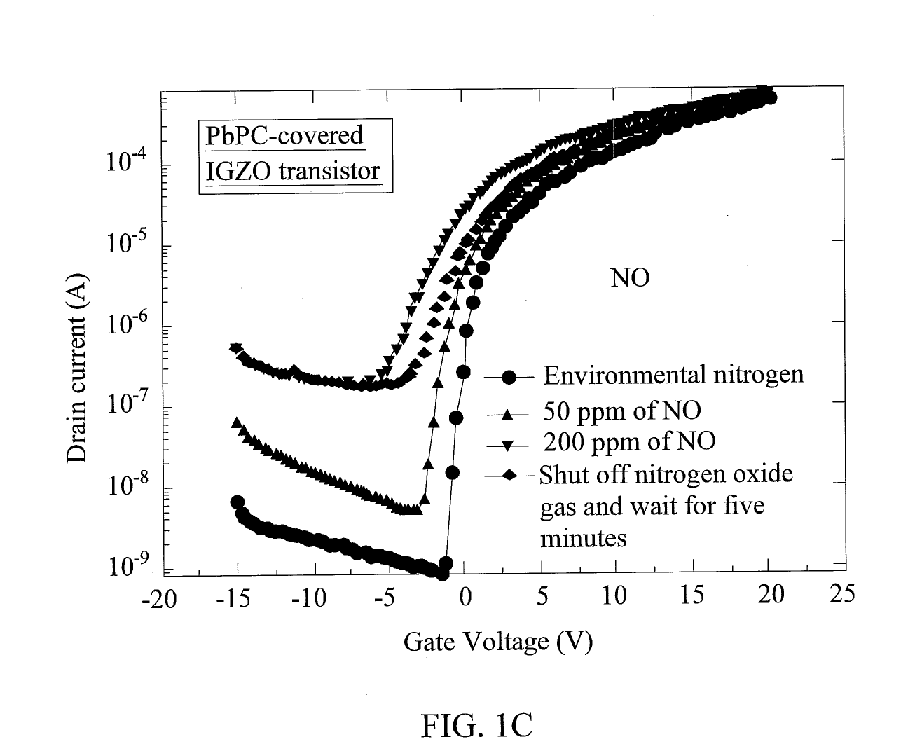

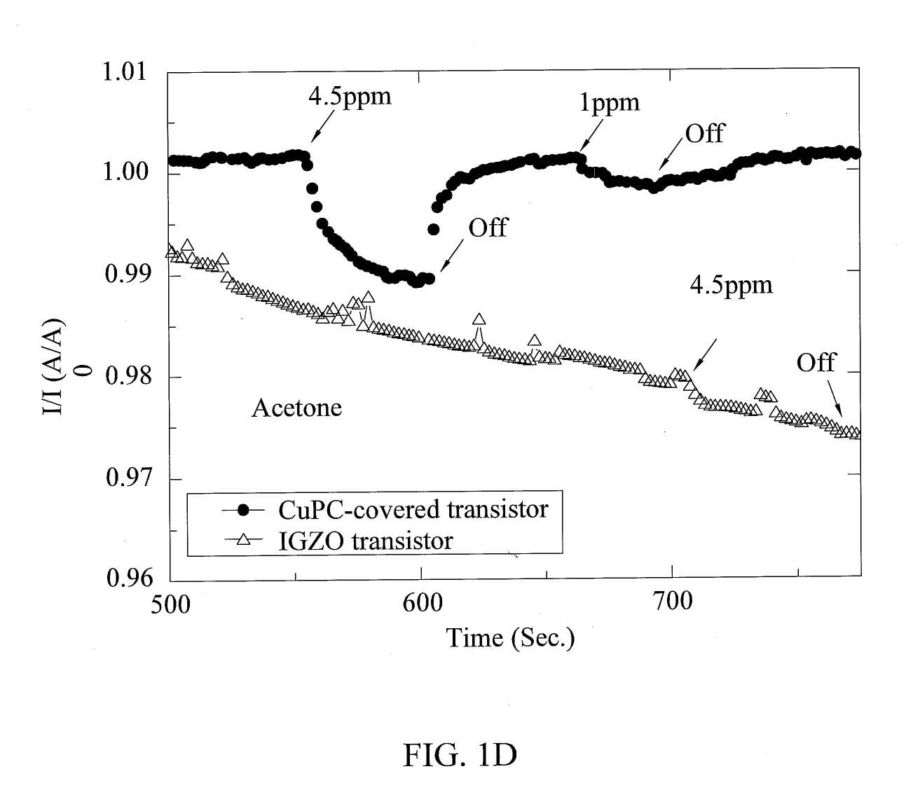

Please refer to FIG. 1A that is a schematic view of a biochemical sensor 1 according to a first embodiment of the present invention. As shown, the biochemical sensor 1 includes a substrate 10, a gate 11, a gate insulating layer 12, an active layer 13, a source and a drain, both being denoted by reference numeral 14, and a biochemical sensing layer 15. The gate 11 is arranged on one side of the substrate 10, the gate insulating layer 12 is arranged on one side of the gate 11 opposite to the substrate 10, the active layer 13 is arranged on one side of the gate insulating layer 12 opposite to the gate 11, the source and drain 14 are arranged on one side of the active layer 13 opposite to the gate insulating layer 12, and the biochemical sensing layer 15 is arranged on one side of the active layer 13 opposite to the gate insulating layer 12 and located between the source 14 and the drain 14.

In the first embodiment, the substrate 10 can be a silicon substrate or a glass substrate; the gate can be aluminum, copper, gold, or polycrystalline silicon; the gate insulating layer 12 can be silicon dioxide or silicon nitride; the active layer 13 can be monocrystalline silicon, polycrystalline silicon, or indium gallium zinc oxide (IGZO); the source and drain 14 can be aluminum, copper or gold; and the biochemical sensing layer 15 can include one single layer or multiple layers, be provided with a micro-nano structure, or be a monomolecular layer (micro-molecule, macromolecule, such as DNA). The biochemical sensing layer 15 is selected according to the physical and chemical properties of an analyte. In some preferred embodiments, the biochemical sensing layer 15 can include, but not limited to, 3-Hexylthiophene (P3HT), lead phthalocyanine (PbPC), or copper phthalocyanine (CuPC), or the like. The biochemical sensor 1 according to the present invention can be used to sense liquids, gases, and solids, such as suspended particles.

Please refer to FIGS. 1B to 1D, which illustrate the use of the biochemical sensor according to the first embodiment of the present invention to sense gas and liquid. As shown in the left part of FIG. 1B, the biochemical sensor in the first embodiment may have an active layer 13 being IGZO and a biochemical sensing layer 15 being P3HT. Since ammonia (NH₃) molecules are polar molecules, they are attached to the surface of the biochemical sensing layer (P3HT) 15 via van der Waals force. The polar molecules of ammonia would trap carriers in P3HT (deep acceptor-like trap state) to affect the carrier distribution in P3HT. Meanwhile, this effect also indirectly affects the carriers in the active layer (IGZO) 13 below the biochemical sensing layer 15, so that the IGZO transistor, which is originally not reactive with ammonia, can be now used to sense ammonia. In addition, P3HT can also be used to sense nitrogen monoxide gas (NO). While the reaction between IGZO and NO is irreversible and independent of concentration, the reaction between the P3HT-covered IGZO and NO is reversible and concentration-dependent, as shown in the right part of FIG. 1B.

In FIG. 1C, the biochemical sensor in the first embodiment has an active layer 13 being IGZO and a biochemical sensing layer 15 being PbPC. FIG. 1C shows gate voltage to drain current (Vg-Id) curves of the PbPC-covered IGZO transistor at different NO concentration levels. By covering the active layer (IGZO) 13 with PbPC (i.e. the biochemical sensing layer 15), the biochemical sensor 1 according to the first embodiment of the present invention can have largely upgraded sensitivity to nitrogen monoxide, compared to a standard device. As can be seen in FIG. 1C, when 50 ppm of nitrogen monoxide is introduced into the biochemical sensor, there is almost a ten times change in the off-current of the transistor. Although the first embodiment as shown in FIG. 1C has irreversible characteristic at room temperature, its characteristic can recover to an original state when being treated by vacuum heating. The recovered device still maintains the characteristic of being able to react with nitrogen monoxide.

In FIG. 1D, the biochemical sensor in the first embodiment has an active layer 13 being IGZO and a biochemical sensing layer 15 being CuPC. FIG. 1D shows changes of current in IGZO transistor and CuPC-covered IGZO transistor at different acetone concentration levels. As can be seen from FIG. 1D, the CuPC-covered IGZO transistor apparently presents reversible reaction with acetone while the IGZO transistor without the CuPC layer does not present any apparent change in current.

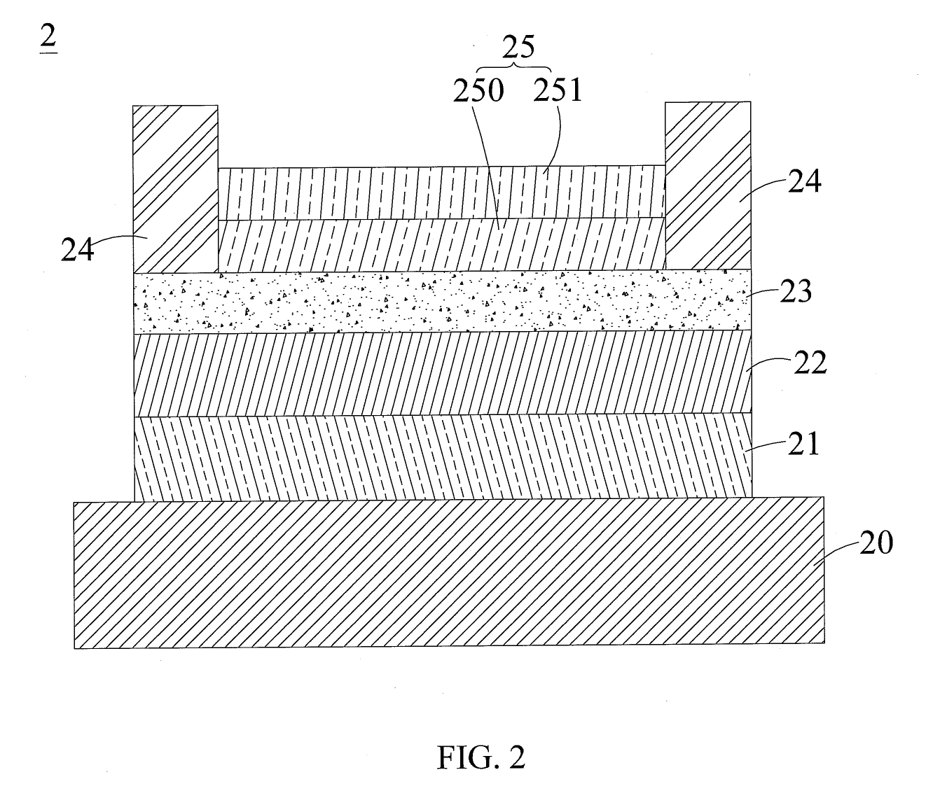

Please refer to FIG. 2 that is a schematic view of a biochemical sensor 2 according to a second embodiment of the present invention. As shown, the biochemical sensor 2 includes a substrate 20, a gate 21, a gate insulating layer 22, an active layer 23, a source and a drain, both being denoted by reference numeral 24, and a biochemical sensing layer 25. The gate 21 is arranged on one side of the substrate 20, the gate insulating layer 22 is arranged on one side of the gate 21 opposite to the substrate 20, the active layer 23 is arranged on one side of the gate insulating layer 22 opposite to the gate 21, the source and drain 24 are arranged on one side of the active layer 23 opposite to the gate insulating layer 22, and the biochemical sensing layer 25 is arranged on one side of the active layer 23 opposite. to the gate insulating layer 22 and located between the source 24 and the drain 24. The second embodiment is different from the first embodiment mainly in that the biochemical sensing layer 25 is composed of a first biochemical sensing sublayer 250 and a second biochemical sensing sublayer 251. The first biochemical sensing sublayer 250 is arranged on one side of the active layer 23 opposite to the gate insulating layer 22, and is located between the source 24 and the drain 24; and the second biochemical sensing sublayer 251 is arranged on one side of the first biochemical sensing sublayer 250 opposite to the active layer 23.

In the second embodiment, the biochemical sensing layer 25 with the multilayered structure can be effectively attached to the active layer 23 to overcome the problem of poor adhesion thereof. Due to connection via multiple layers, the second biochemical sensing sublayer 251 being actually used to sense a biochemical substance can be effectively attached to the active layer 23 via the first biochemical sensing sublayer 250.

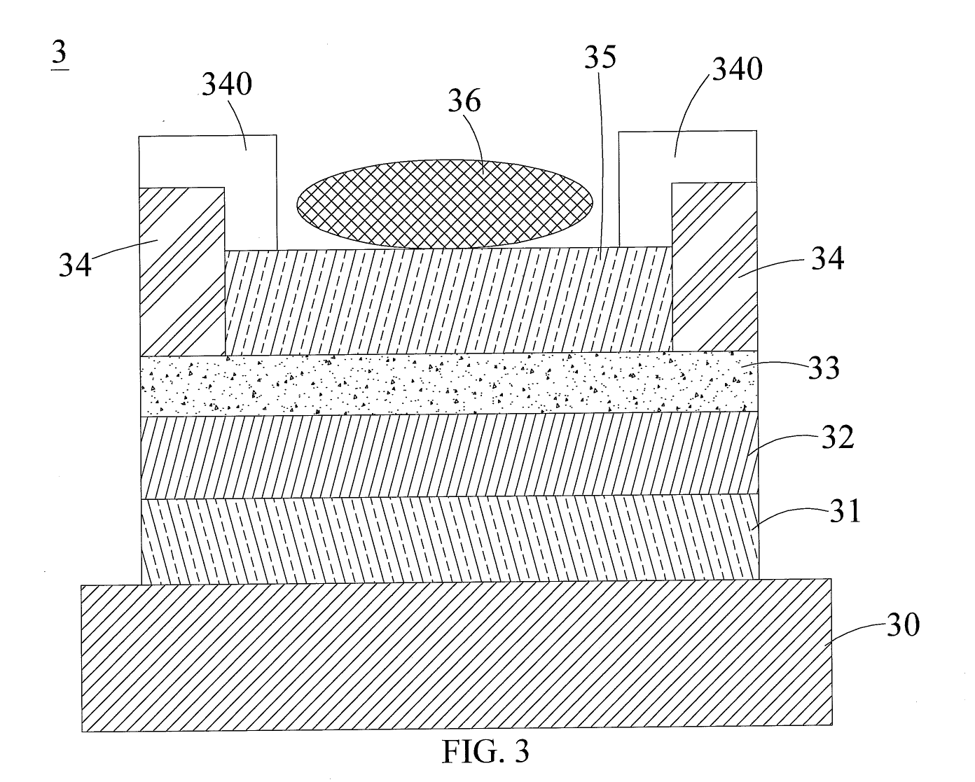

Please refer to FIG. 3 that is a schematic view of a biochemical sensor 3 according to a third embodiment of the present invention. As shown, the biochemical sensor 3 is generally structurally similar to the biochemical sensor 1 and includes from bottom to top a substrate 30, a gate 31, a gate insulating layer 32, an active layer 33, a source and a drain, both being denoted by reference numeral 34, and a biochemical sensing layer 35. The biochemical sensor 3 is different from the biochemical sensor 1 mainly in further having an insulating layer 340 provided on sidewalls of the source and drain 34. With the insulating layer 340, the source 34 and the drain 34 would not be electrically connected to each other via a liquid 36 being sensed with the biochemical sensor 3.

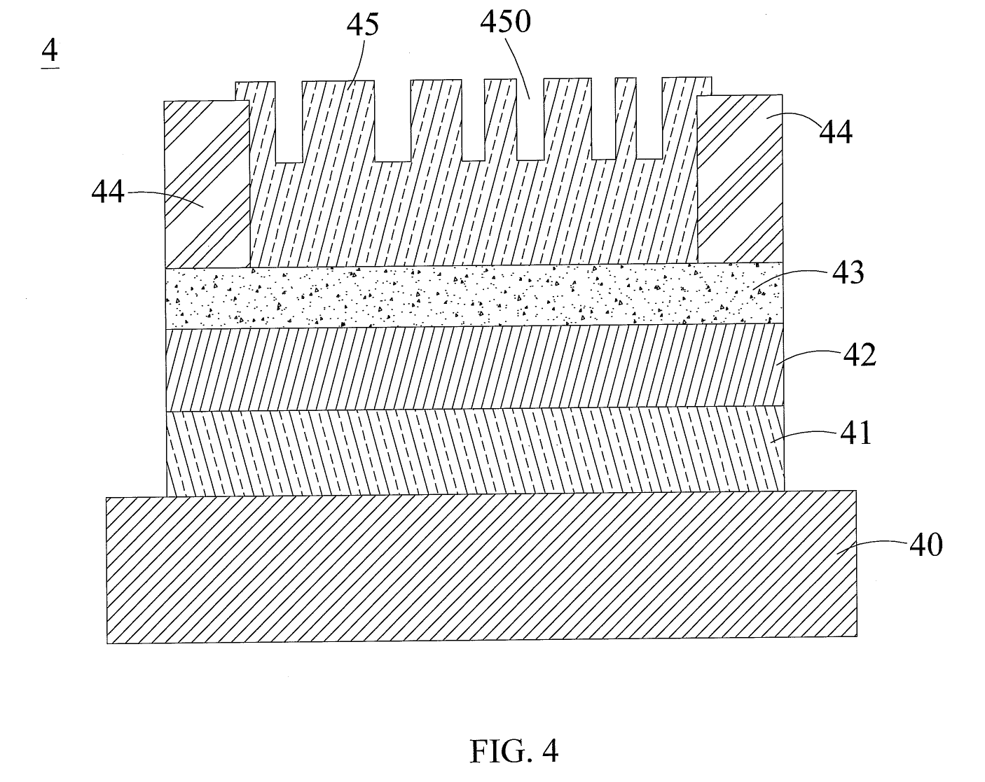

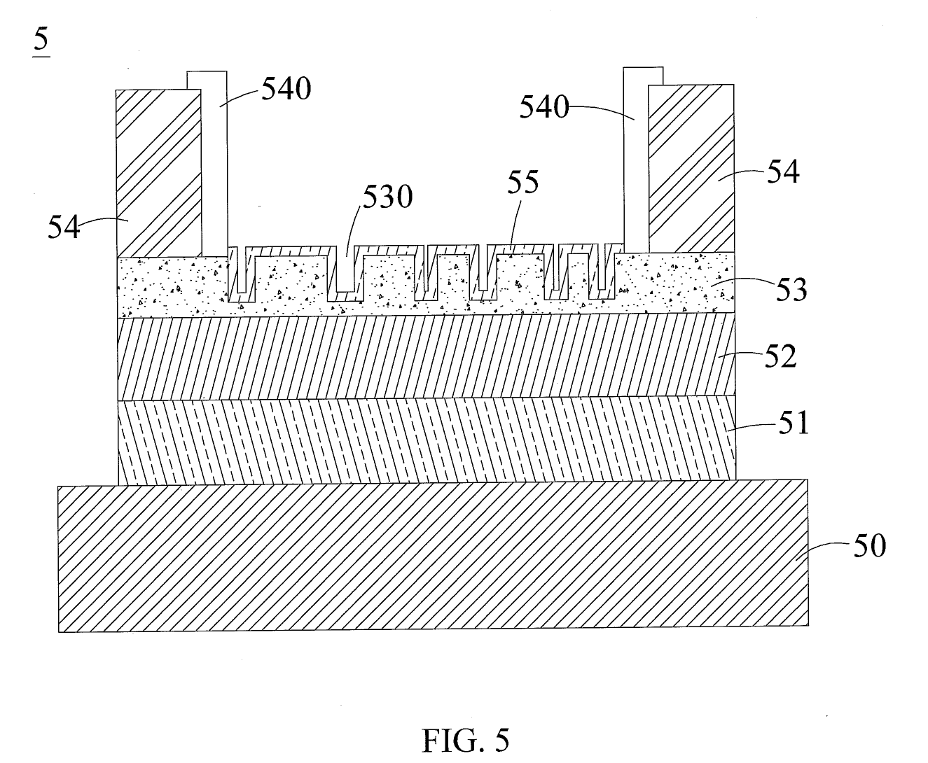

FIG. 4 is a schematic view of a biochemical sensor 4 according to a fourth embodiment of the present invention, which is generally structurally similar to the first embodiment and includes from bottom to top a substrate 40, a gate 41, a gate insulating layer 42, an active layer 43, a source and a drain, both being denoted by reference numeral 44, and a biochemical sensing layer 45. The biochemical sensor 4 is different from the biochemical sensor 1 mainly in that the biochemical sensing layer 45 is cut to form a plurality of first hole structures 450 thereon. The first hole structures 450 give the biochemical sensing layer 45 an increased contact area with the analyte, and accordingly, enables increased sensing speed of the biochemical sensor 4. FIG. 5 is a schematic view of a biochemical sensor 5 according to a fifth embodiment of the present invention, which is generally structurally similar to the third embodiment and includes from bottom to top a substrate 50, a gate 51, a gate insulating layer 52, an active layer 53, a source and a drain, both being denoted by reference numeral 54, a biochemical sensing layer 55, and an insulating layer 540 provided on sidewalls of the source and drain 54. The biochemical sensor 5 is different from the biochemical sensor 3 mainly in that the active layer 53 is cut to form a plurality of second hole structures 530 thereon, and the biochemical sensing layer 55 is arranged on the second hole structures 530 of the active layer 53. With these arrangements, the biochemical sensing layer 55 can also provide an increased contact area with the analyte and enable increased sensing speed to achieve the same function as the biochemical sensor 4 in the fourth embodiment.

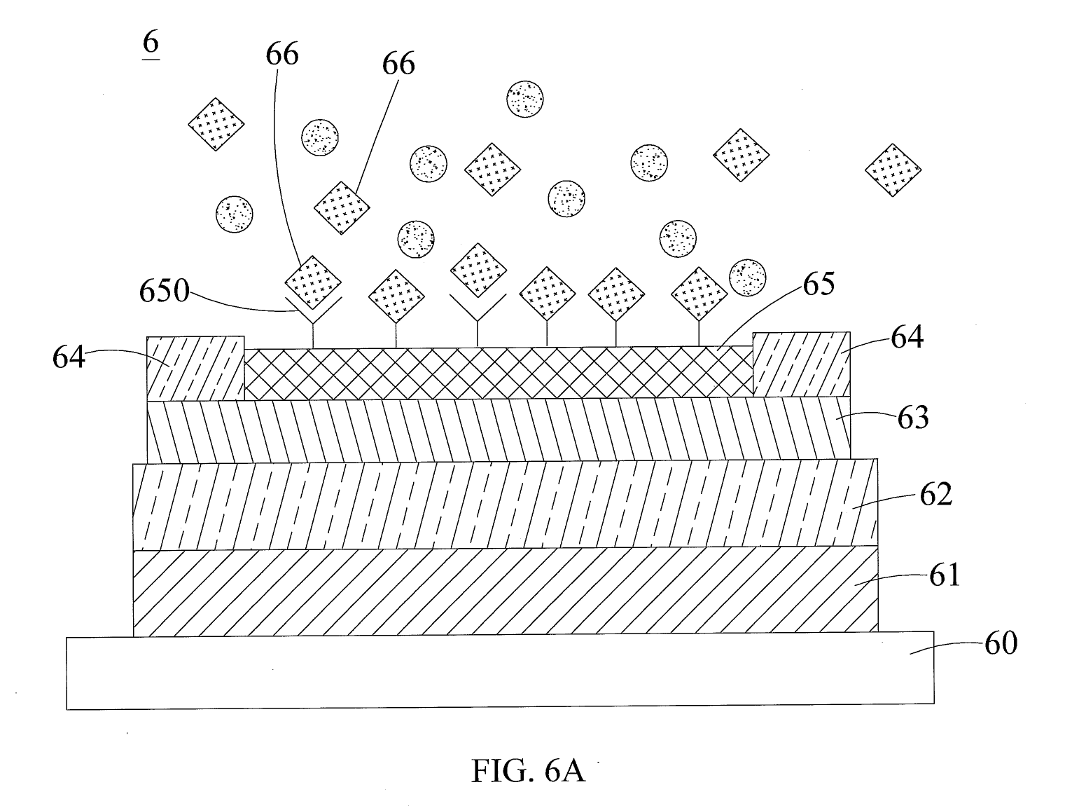

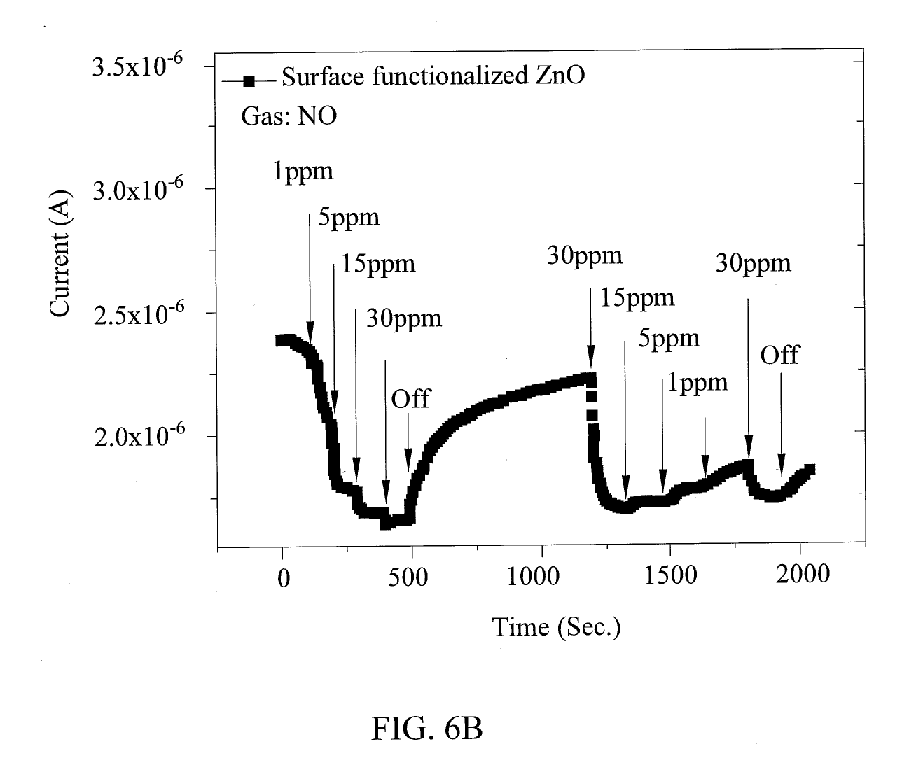

FIG. 6A is a schematic view of a biochemical sensor 6 according to a sixth embodiment of the present invention, and FIG. 6B illustrates the use of the biochemical sensor 6 to sense gas. As shown, the biochemical sensor 6 also includes from bottom to top a substrate 60, a gate 61, a gate insulating layer 62, an active layer 63, a source and a drain, both being denoted by reference numeral 64, and a biochemical sensing layer 65. In the sixth embodiment, the biochemical sensing layer 65 includes a zinc oxide (ZnO) layer formed through solution process, and the ZnO layer is then surface functionalized by bonding hemin 650 thereto. Since there are hydroxyl groups (OH) on the ZnO surface, and the hydroxyl groups can bond to carboxyl groups (COOH) of hemin to form a monomolecular layer of hemin on the ZnO surface, the biochemical sensing layer 65 can be used to sense nitrogen oxide 66 as shown in FIG. 6B.

Please note, one of ordinary skill in the art, to which the present invention pertains, can understand from the sixth embodiment of the present invention that, when it is desired to add a layer of selective sensing molecular layer, such as heme, on the active layer of a metal-oxide-semiconductor thin-film transistor (MOS TFT) but the monomolecular layer could not directly attach to the metal oxide, it is then necessary to additionally provide one layer of substance, such as a metal layer or an oxide layer, between the monomolecular layer and the active layer for the monomolecular layer to attach to the active layer, so that the MOS TFT can provide the sensing function. Therefore, any simple change or modification in the above-described embodiments made by one of ordinary skill in the art is also included in the scope of the present invention as defined by the appended claims.

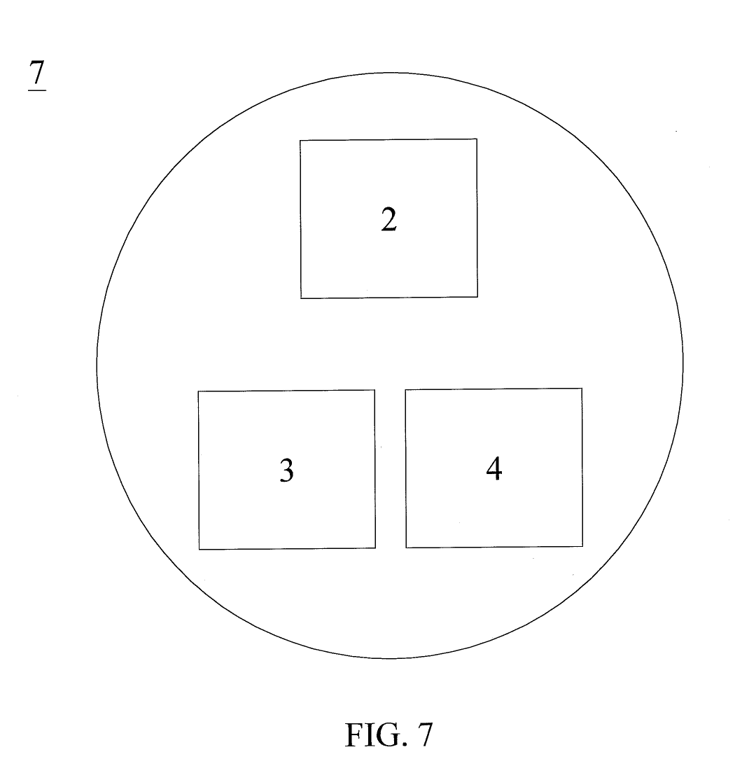

Please refer to FIG. 7 that is a schematic view of a biochemical sensor array 7 according to the present invention. As shown, in the biochemical sensor array 7, there are included a plurality of biochemical sensors 2, 3 and 4. With the illustrated embodiments of the present invention, one of ordinary skill in the art, to which the present invention pertains, can easily integrate different types of biochemical sensors on the same one substrate to achieve the purpose of multi-sensing and increased sensing selectivity.

While the above description of the biochemical sensor of the present invention has also introduced a concept about the method of manufacturing a biochemical sensor, a flowchart showing more detailed steps of such method according to the present invention is nevertheless provided herein for the purpose of clarity.

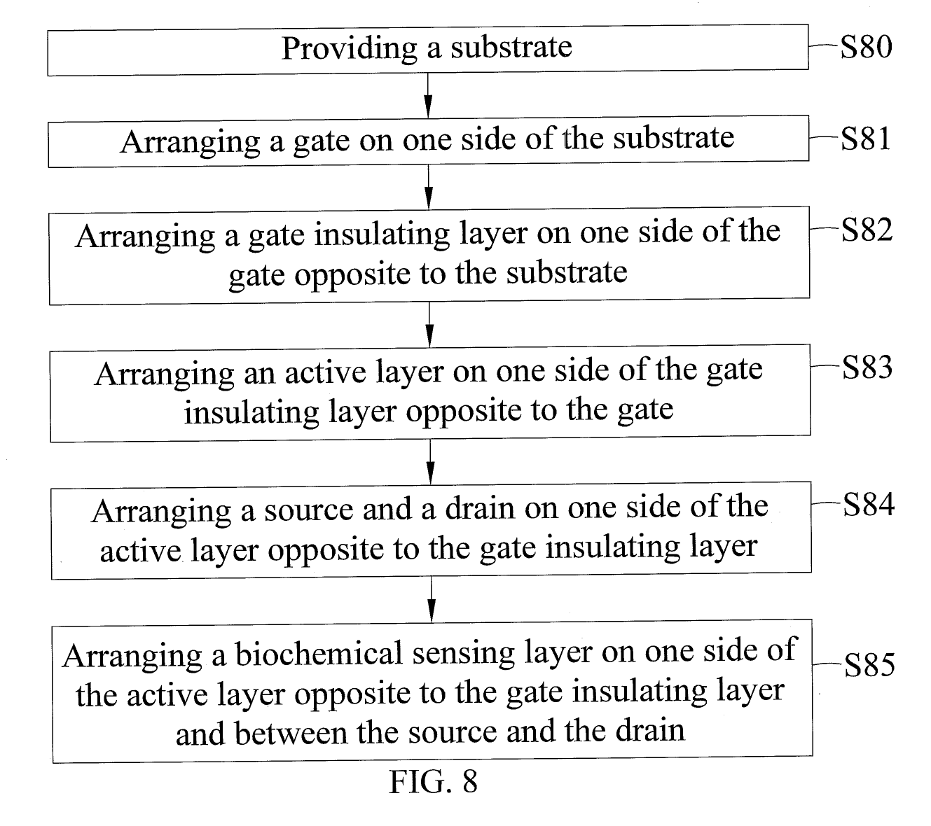

Please refer to FIG. 8 that is a flowchart showing the steps S80 to S85 included in a method of manufacturing biochemical sensor according to the present invention.

In the step S80, a substrate is provided.

In the step S81, a gate is arranged on one side of the substrate.

In the step S82, a gate insulating layer is arranged on one side of the gate opposite to the substrate.

In the step S83, an active layer is arranged on one side of the gate insulating layer opposite to the gate.

In the step S84, a source and a drain are arranged on one side of the active layer opposite to the gate insulating layer.

And, in the step S85, a biochemical sensing layer is arranged on one side of the active layer opposite to the gate insulating layer and between the source and the drain.

Wherein, the step S85 further includes the following steps S850 and S851 (not shown).

In the step S850, a first biochemical sensing sublayer is arranged on one side of the active layer opposite to the gate insulating layer and between the source and the drain; and in the step S851, a second biochemical sensing sublayer is arranged on one side of the first biochemical sensing sublayer opposite to the active layer.

The method of manufacturing biochemical sensor according to the present invention may further include a step S860 (not shown) after the step S85. In the step S860, the biochemical sensing layer is surface functionalized to thereby have biochemical selectivity.

Alternatively, the method of manufacturing biochemical sensor according to the present invention may further include a step S861 (not shown) after the step S85. In the step S861, at least one first hole structure is formed on a top surface of the biochemical sensing layer to thereby provide increased contact area on the biochemical sensing layer.

Alternatively, the method of manufacturing biochemical sensor according to the present invention may further include a step S830 (not shown) after the step S83. In the step S830, at least one second hole structure is formed on a top surface of the active layer to thereby provide increased contact area on the active layer.

In the method of the present invention, the biochemical sensing layer is selected according to the physical and chemical properties of an analyte, and is preferably selected from the group consisting of 3-Hexylthiophene (P3HT), lead phthalocyanine (PbPC), and copper phthalocyanine (CuPC).

Since the details and the implementation of the method of manufacturing biochemical sensor according to the present invention have already been recited in the above description of the biochemical sensor of the present invention, they are not repeatedly discussed herein.

In brief, with the biochemical sensor and method of manufacturing the same according to the present invention, a biochemical sensing layer is arranged on the active layer to thereby enable detection of various types of biochemical substances, such as ammonia, nitrogen oxide, acetone, DNA molecules, protein and the like, on an MOS transistor. On the other hand, with the biochemical sensor and method of manufacturing same according to the present invention, the biochemical sensing layer can be surface functionalized, or a plurality of biochemical sensors can be integrated on one single substrate, so as to provide the biochemical sensor with increased detection sensitivity and sensing selectivity.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A biochemical sensor, comprising:
a substrate;
a gate being arranged on one side of the substrate;
a gate insulating layer being arranged on one side of the gate opposite to the substrate;
an active layer being arranged on one side of the gate insulating layer opposite to the gate;
a source and a drain being arranged on one side of the active layer opposite to the gate insulating layer; and
a biochemical sensing layer being arranged on one side of the active layer opposite to the gate insulating layer and between the source and the drain.

2. The biochemical sensor according to claim 1, wherein the biochemical sensing layer further includes a first biochemical sensing sublayer arranged on one side of the active layer opposite to the gate insulating layer and between the source and the drain, and a second biochemical sensing sublayer arranged on one side of the first biochemical sensing sublayer opposite to the active layer.

3. The biochemical sensor according to claim 1, wherein the biochemical sensing layer is surface functionalized to thereby have biochemical selectivity.

4. The biochemical sensor according to claim 1, wherein the biochemical sensing layer is provided on a top surface with at least a first hole structure to enable increased contact area on the biochemical sensing layer.

5. The biochemical sensor according to claim 1, wherein the active layer is provided on a top surface with at least a second hole structure to enable increased contact area on the active layer.

6. The biochemical sensor according to claim 1, wherein the biochemical sensing layer is selected from the group consisting of 3-Hexylthiophene (P3HT), lead phthalocyanine (PbPC), and copper phthalocyanine (CuPC).

7. A method of manufacturing a biochemical sensor, comprising the following steps:
providing a substrate;
arranging a gate on one side of the substrate;
arranging a gate insulating layer on one side of the gate opposite to the substrate;
arranging an active layer on one side of the gate insulating layer opposite to the gate;
arranging a source and a drain on one side of the active layer opposite to the gate insulating layer; and
arranging a biochemical sensing layer on one side of the active layer opposite to the gate insulating layer and between the source and the drain.

8. The method as claimed in claim 7, wherein the biochemical sensing layer further includes a first and a second biochemical sensing sublayer, and the method of manufacturing the biochemical sensor further comprising the following steps:
arranging the first biochemical sensing sublayer on one side of the active layer opposite to the gate insulating layer and between the source and the drain; and
arranging the second biochemical sensing sublayer on one side of the first biochemical sensing sublayer opposite to the active layer.

9. The method as claimed in claim 7, further comprising the following step:
functionalizing a top surface of the biochemical sensing layer, so that the biochemical sensing layer has biochemical selectivity.

10. The method as claimed in claim 7, further comprising the following step:
forming a first hole structure on a top surface of the biochemical sensing layer; wherein the first hole structure enables increased contact area on the biochemical sensing layer.

11. The method as claimed in claim 7, further comprising the following step:
forming a second hole structure on a top surface of the active layer; wherein the second hole structure enables increased contact area on the active layer.

12. The method as claimed in claim 7, wherein the biochemical sensing layer is selected from the group consisting of 3-Hexylthiophene (P3HT), lead phthalocyanine (PbPC), and copper phthalocyanine (CuPC).
